(19) United States
(12) Patent Application Publication
(10) Pub. No.: US 2025/0191244 A1
(43) Pub. Date: Jun. 12, 2025

(54) METHOD FOR CHECKING A GRAPHICS FILE

(71) Applicant: dSPACE GmbH, Paderborn (DE)

(72) Inventor: Tobias SIELHORST, Paderborn (DE)

(73) Assignee: dSPACE GmbH, Paderborn (DE)

(21) Appl. No.: 19/051,895

(22) Filed: Feb. 12, 2025

Related U.S. Application Data
(63) Continuation of application No. PCT/EP2023/064548, filed on May 31, 2023.

(30) Foreign Application Priority Data
Aug. 12, 2022 (DE) 10 2022 120 421.9

(51) Int. Cl. G06T 11/00

(52) U.S. Cl. CPC G06T 11/00; G06T 2210/32

(57) ABSTRACT

A method for checking a graphics file is provided. A graphics file is provided having graphics information, which leads to a graphical representation, corresponding to the graphics information, of graphics elements on a display device of the computer system. The graphics file has in each case a predefined annotation for at least some of the graphics elements and the graphics file has predefined graphics structure information that specifies, at least for some of the graphics elements, which of these graphics elements must be displayed as connected to one another during the graphical representation on the display device. A modified version of the graphics file is received in which at least one piece of graphics information has been modified such that it leads to a different graphical representation on the display device. The modified version of the graphics file is thereafter checked.

This nonprovisional application is a continuation of International Application No. PCT/EP2023/064548, which was filed on May 31, 2023, and which claims priority to German Patent Application No. 10 2022 120 421.9, which was filed in Germany on Aug. 12, 2022, and which are both herein incorporated by reference.

### BACKGROUND OF THE INVENTION

### Field of the Invention

The invention relates to a method for checking a graphics file comprising the method steps: providing a graphics file having graphics information, which graphics file, when processed in a graphics program implemented on a computer system, results in a graphical representation, corresponding to the graphics information, of graphics elements on a display device of the computer system, and receiving a modified version of the graphics file in which at least one piece of graphics information has been modified such that a different graphical representation is produced on the display device.

### Description of the Background Art

PC-based simulation platforms are known for the validation of software of electronic control units (ECU) at various development phases. Such simulation platforms make it possible to simulate a variety of different models—from functional models through networks of virtual control units to bus systems and vehicle models—even at early development phases. Thus, dSPACE GmbH offers a suitable system under the name VEOS®, for example. VEOS® is a PC-based simulation platform that supports SIL tests (SIL=software in the loop) in the development of electronic control units (ECUs). VEOS® makes it possible to simulate a variety of different models, including functional models, functional mockup units (FMUs), virtual control units (V-ECUs), and vehicle models, independently of any simulation hardware in early phases of development. In scenarios with multiple models, VEOS® supports the import, connection, and execution of any number of functional and system models based on Simulink® or Functional Mockup Interface (FMI), and in this way expands the functional scope of applications.

Now, if a simulation topology is created within the framework of such a simulation task, it is generally also desirable to document this topology graphically. Until now, such documentation has frequently been created such that a screenshot of the GUI (Graphical User Interface) showing the simulation topology is recorded for documentation purposes. The problem sometimes arises here, however, that the simulation topology is so large that it does not by any means fit on the screen. Consequently, it is also an option to manually reproduce the simulation topology for viewing using a graphics program.

Automating this work, e.g., by script, is difficult. A universally applicable script cannot do justice to the task, because depending on the context, different aspects are important or must be represented in a particular manner in the documentation. When there are modifications to the model determining the simulation topology, these must be painstakingly updated in the manually generated view, and are not necessarily complete.

### SUMMARY OF THE INVENTION

It is therefore an object of the invention to make possible reliable, efficient, and dependably customizable documentation of a simulation topology.

According to an example of the invention, therefore, a method is provided for checking a graphics file, comprising the following steps: providing a graphics file having graphics information, which graphics file, when processed in a graphics program implemented on a computer system, results in a graphical representation, corresponding to the graphics information, of graphics elements on a display device of the computer system, wherein the graphics file has in each case a predefined annotation for at least some of the graphics elements and wherein the graphics file has predefined graphics structure information that specifies, for at least some of the graphics elements, which of these graphics elements must be displayed as connected to one another in the graphical representation on the display device; receiving a modified version of the graphics file in which at least one piece of graphics information has been modified such that a different graphical representation is produced on the display device; and checking the modified version of the graphics file to ascertain whether, in the graphical representation on the display device, this graphical representation corresponds to the predefined graphics structure information and whether, for each predefined annotation, exactly one graphics element with this annotation is displayed.

It is therefore an essential point of the invention to check the modified version of the graphics file to ascertain whether, in the graphical representation on the display device, this graphical representation corresponds to the predefined graphics structure information, which is to say continues to correctly reflect the structure of the model, and, for each predefined annotation, exactly one graphics element with this annotation is displayed, or in other words is complete.

The modified version of the graphics file, in which at least one piece of graphics information has been modified such that a different graphical representation is produced on the display device, can have any modifications, such as modification of the size, the shape, and/or the location of a graphics element. A modification of this nature can be due to causes such as that the representation must meet certain guidelines.

When it is stated that a check is made to ascertain whether, for each predefined annotation, exactly one graphics element with this annotation is displayed, it is fundamentally possible that this annotation is displayed as associated with the respective graphics element in the graphical representation on the display device. Such a display of the respective annotation is not absolutely necessary within the scope of the invention, however. It is therefore also possible that an annotation is associated with a graphics element but that this annotation is not displayed in the graphical representation on the display device.

Now, the checking can be connected with further method steps. Thus, it is possible within the scope of a preferred improvement of the invention that, for example, the method has the following additional method step: graphical representation of the differences in the modified version of the graphics file from the predefined graphics structure information. In this way, it can be identified easily if the represented structure no longer corresponds to the predefined model.

For example, a method step can be provided in which a representation takes place of the predefined annotation for which no graphics element with that annotation is displayed. This representation can be a graphical representation and/or a representation in the form of a text notification, among other possibilities. In this way, missing graphics elements can be identified easily.

The graphics file can be provided in different formats. According to a preferred improvement of the invention, however, provision is made that the graphics file can be provided in a freely editable vector format. This facilitates adaptation and revision of the graphics file.

The graphics elements can have different information content in principle. According to a preferred improvement of the invention, however, the graphics elements for which predefined annotations and predefined graphics structure information are present describe a simulation topology. If a simulation topology is created within the framework of a simulation task, it is generally also desirable to document this topology graphically. The present invention facilitates this documentation and can ensure that revisions of the documentation do not lead to errors in the modified graphics file.

A modification of the graphics file can be accomplished in different ways. According to a preferred improvement of the invention, however, the modified version of the graphics file is obtained by means of an automated modification of the graphics file. It is very especially preferred in this case that the automated modification of the graphics file is accomplished according to at least one predetermined rule.

The checking of the modified version of the graphics file can include various aspects. For example, during checking of the modified version of the graphics file, it can be also checked whether, in the graphical representation on the display device, this graphical representation is within a predetermined contrast range. Such a check can ensure that the graphical representation remains easily perceivable and potentially can be further processed. In this context, it is preferred that, during checking of the modified version of the graphics file, it is checked whether, in the graphical representation on the display device, all graphics elements are displayed in a predetermined size range. Moreover, during checking of the modified version of the graphics file, it is preferably checked whether, in the graphical representation on the display device, none of the graphics elements and/or annotations overlap one another. All of this serves the purpose of clear and maximally error-free documentation.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 schematically shows a method for checking a graphics file according to an example of the invention,

FIG. 2 shows an example for documentation of a simulation system according to an example of the invention,

FIG. 3 shows a revised version of the example from FIG. 2, and

FIG. 4 shows an updated version of the example from FIG. 3.

### DETAILED DESCRIPTION

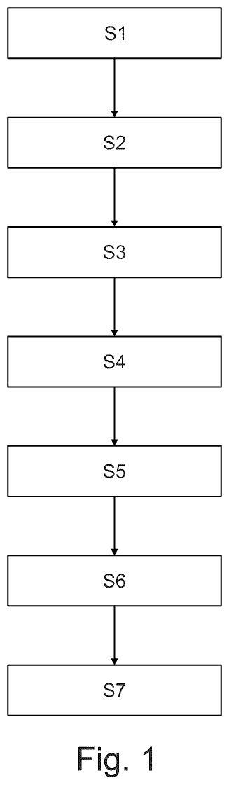

A method for checking a graphics file according to an example of the invention is schematically visible in FIG. 1. In a first step S1, a graphics file having graphics information is provided, which graphics file, when processed in a graphics program implemented on a computer system, results in a graphical representation, corresponding to the graphics information, of graphics elements on a display device of the computer system. The graphics elements in this case describe a simulation topology of a simulation task such as a SIL test under the VEOS® platform. The graphics file is provided in a freely editable vector format.

The graphics file has one predefined annotation each for all graphics elements. In addition, the graphics file has graphics structure information that is predefined and therefore should not be modified, and that specifies, for the graphics elements, which of these graphics elements must be displayed as connected to one another in the graphical representation on the display device. The graphics structure information thus represents a display rule as to what the connection structure must be of the graphics elements among one another in the display.

If the graphics file has now been revised by a user, for instance in order to adapt it to a predetermined documentation format with particular guidelines, then it should nevertheless continue to represent complete and correct documentation. Therefore, provision is made in a further step S2 that the modified version of the graphics file, in which at least one piece of graphics information has been modified such that a different graphical representation is produced on the display device, is received. In step S3, it is then checked for this modified graphics file whether, in the graphical representation on the display device, the graphical representation produced by the modified graphics file corresponds to the predefined graphics structure information and also whether, for each predefined annotation, exactly one graphics element with this annotation is displayed.

This step S3 thus serves as a check of the completeness of its content (Is exactly one graphics element displayed for each annotation?) as well as to check its correctness with regard to the connection structure of the graphics elements among one another (Does the graphical representation correspond to the predefined graphics structure information?). Here, the annotations can be displayed in the graphical representation on the display device as associated with the respective graphics element, but this is not absolutely necessary.

Now, if it is determined within the framework of the check that the modified version of the graphics file results in a representation that differs from the predefined graphics structure information, then the way these differences in the modified version of the graphics file from the predefined graphics structure information appear is graphically represented in step S4. Furthermore, the predefined annotation for which no graphics element with that annotation is displayed, if applicable, is displayed in this process.

Step S4 is followed by additional checking steps: in step S5, the modified version of the graphics file is checked to ascertain whether, in the graphical representation on the display device, this graphical representation is within a predetermined contrast range. This is followed by step S6, in which it is checked whether, in the graphical representation on the display device, all graphics elements are displayed in a predetermined size range. This is followed, finally, by a step S7, in which it is checked whether, in the graphical representation on the display device, none of the graphics elements and/or visible annotations overlap one another. These steps can of course also be carried out in a different order and, moreover, these steps can also be carried out before step 3.

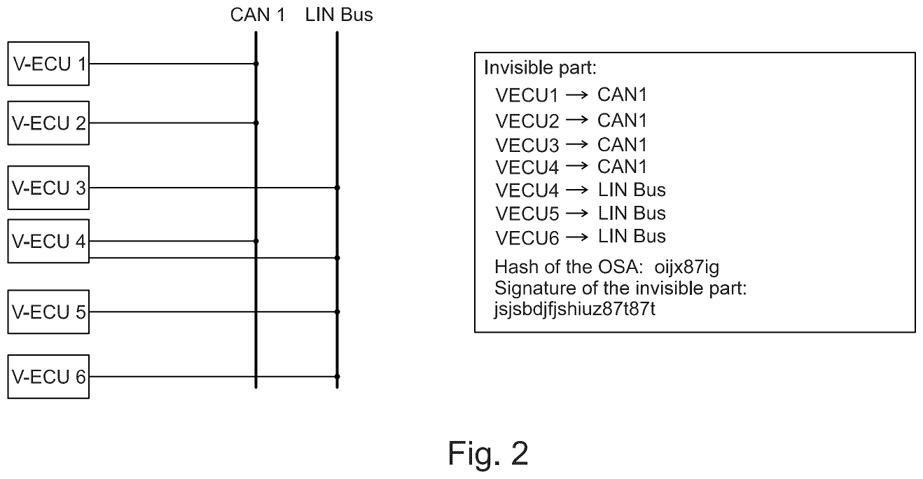

There now follows, with reference to FIGS. 2 to 4, the description of a concrete example for documentation of a simulation system with six virtual control units (V-ECUs) that are connected to one another via two buses (CAN1, LIN bus). In its left side, FIG. 2 shows a simple view of this simulation system, which would, in principle, be suitable for documentation. This view is provided in the form of a graphics file in a freely editable vector format. In the present case, an invisible, signed annotation that specifies how the model is structured belongs to this graphics file. This annotation is shown in FIG. 2 on the right side, and states which V-ECU is connected to which bus. Thus, VECU1 is connected to the bus CAN1, VECU2 likewise to the bus CAN1, etc.

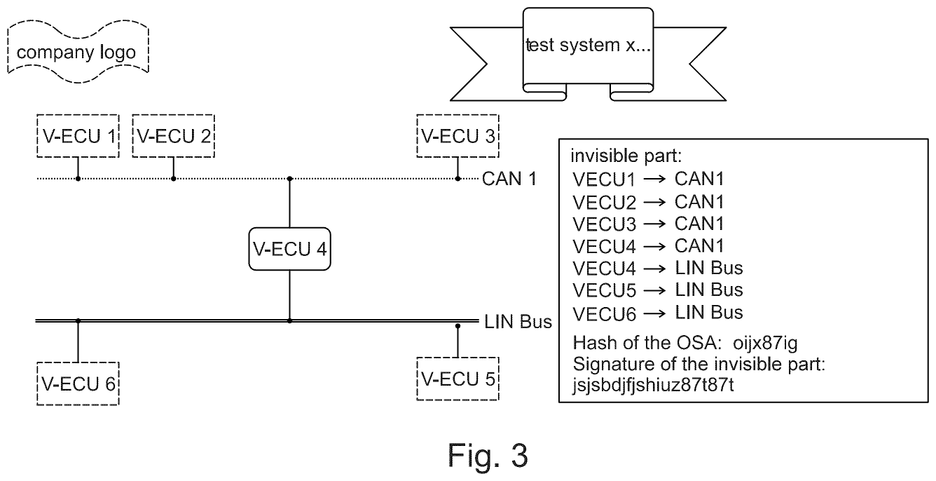

A user now modifies this view with a vector graphics editor that is suitable for the vector graphics format by editing the graphics accordingly. FIG. 3 now shows the same simulation system, which has, however, been modified in various ways by the user. Namely, objects have been added or modified in terms of location or style. Ultimately, however, it shows the same system as the original graphics file. The annotations in the invisible part have also remained the same. Nor should these be modified, since they describe the structure of the model.

It can happen during the editing process, however, that objects are lost or visually disappear owing to the editing, because the vector graphics editor allows essentially any type of modifications. Therefore, a check is made at this time on the basis of the annotation as to whether the vector graphics match the system predefined by the annotations. In this process, it is first checked whether the invisible annotations are present and have integrity. Then it is checked whether all display objects belonging to the annotations are still present in the visible part of the graphic. In this way, it is ensured that no display objects have been deleted accidentally or intentionally. Then the visibility of the objects is checked for contrast, size, and hiddenness. If this check was successful, then one can rely on the edited view also being a complete representation of the simulation system.

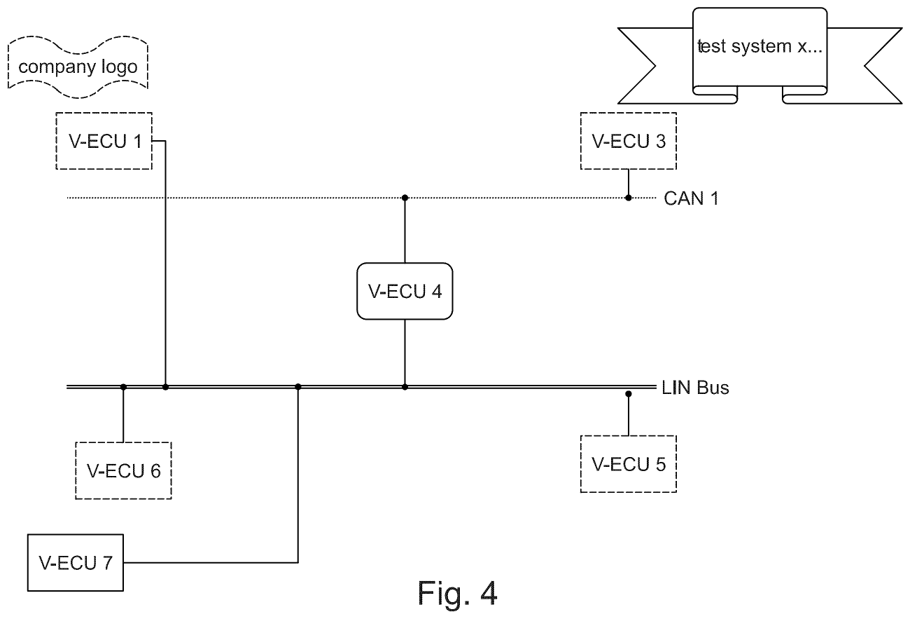

The invention offers yet another advantage: when the simulation system has been updated, the graphics file need not be created completely anew. Instead, it is possible to integrate the differences from the previous version into the documentation. The representation from FIG. 3 is compared with an updated simulation system for this purpose. FIG. 4 shows an updated representation. Here, one connection was relocated, one V-ECU was removed, and one V-ECU was added. This is easily possible in technical terms, since the list of the objects to be represented is known and complete on account of the annotations. After calculating the difference, one can take the old representation, regenerate missing objects, and delete removed objects from the representation.

It is therefore a significant point of the invention to provide sustainable documentation that can be adapted individually in order to make a purposeful statement. The technology of annotated vector graphics used for this purpose is an important component of the invention, since in this way the user can use his preferred editor to produce the documentation in a targeted manner. What is now significant within the scope of the invention is the permitted manipulation of documentation with subsequent automatic integrity checking. Critical for this purpose is a part that is invisible and is not editable with the graphics editor, which part specifies the structure of the model, and on the other hand an editable part with annotations.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for checking a graphics file, the method comprising:
providing a graphics file having graphics information, which graphics file, when processed in a graphics program implemented on a computer system, results in a graphical representation, corresponding to the graphics information, of graphics elements on a display device of the computer system, the graphics file comprising a predefined annotation for at least some of the graphics elements, and the graphics file comprising predefined graphics structure information that specifies, for at least some of the graphics elements, which of these graphics elements must be displayed as connected to one another in the graphical representation on the display device;
receiving a modified version of the graphics file in which at least one piece of graphics information has been modified such that a different graphical representation is produced on the display device;
checking the modified version of the graphics file to ascertain whether, in the graphical representation on the display device, this graphical representation corresponds to the predefined graphics structure information and whether, for each predefined annotation, exactly one graphics element with this annotation is displayed.

2. The method according to claim 1, further comprising: graphically representing the differences in the modified version of the graphics file from the predefined graphics structure information.

3. The method according to claim 1, further comprising: representing the predefined annotation for which no graphics element with that annotation is displayed.

4. The method according to claim 1, wherein the graphics file is provided in a freely editable vector format.

5. The method according to claim 1, wherein the graphics elements for which predefined annotations and predefined graphics structure information are present describe a simulation topology.

6. The method according to claim 1, wherein the modified version of the graphics file is obtained via an automated modification of the graphics file.

7. The method according to claim 6, wherein the automated modification of the graphics file is accomplished according to at least one predetermined rule.

8. The method according to claim 1, wherein, during checking of the modified version of the graphics file, it is also checked whether, in the graphical representation on the display device, this graphical representation is within a predetermined contrast range.

9. The method according to claim 1, wherein, during checking of the modified version of the graphics file, it is also checked whether, in the graphical representation on the display device, all graphics elements are displayed in a predetermined size range.

10. The method according to claim 1, wherein, during checking of the modified version of the graphics file, it is also checked whether, in the graphical representation on the display device, none of the graphics elements and/or visible annotations overlap one another.
